(19) United States
(12) Patent Application Publication
(10) Pub. No.: US 2006/0183258 A1
(43) Pub. Date: Aug. 17, 2006

(54) Imaging system and method for producing semiconductor structures on a wafer by imaging a mask on the wafer with a dipole diaphragm

(76) Inventors: Mario Hennig, Dresden (DE); Wolfram Koestler, Langebrueck (DE); Molela Moukara, Muenchen (DE); Joerg Thiele, Vaterstetten (DE); Thorsten Winkler, Muenchen (DE); Karsten Zeiler, Muenchen (DE)

Correspondence Address: SLATER & MATSIL LLP, 17950 PRESTON ROAD, SUITE 1000, DALLAS, TX, 75252, US

(21) Appl. No.: 11/334,941

(22) Filed: Jan. 19, 2006

(30) Foreign Application Priority Data
Jan. 19, 2005 (DE) 10 2005 003 185.4

(51) Int. Cl. G06F 17/50; H01L 21/00

(52) U.S. Cl. 438/29; 716/19

(57) ABSTRACT

An imaging system having a dipole diaphragm (2) having two diaphragm openings (2b) arranged one behind the other in a dipole axis (y), and a mask having mask structures (20, 23) is used for producing semiconductor structures (10′, 13′) on a wafer (15′) by imaging the mask (25) onto the wafer (15′). The dipole diaphragm (2) is provided for the imaging of the mask (25), and the mask (25), for producing main semiconductor structures (10; 10′) on the wafer (15′), has main mask structures (20) parallel to an imaging axis (x) running perpendicular to the dipole axis (y). At least one connecting mask structure (23′) oriented obliquely with respect to the dipole axis (y) at least in sections is formed on the mask (25), which structure connects at least two main mask structures (20) to one another.

This application claims priority to German Patent Application 10 2005 003 185.4, which was filed Jan. 19, 2005, and is incorporated herein by reference.

### TECHNICAL FIELD

The invention relates to an imaging system for producing semiconductor structures on a wafer and to a method therefor.

### BACKGROUND

It is known to produce semiconductor circuits from wafers, which are exposed through a mask in such a way that mask structures of the mask are imaged as semiconductor structures on the wafer. The mask structures are usually either opaque or transparent to the light waves used during the imaging exposure. During the imaging operation, the opaque mask structures cover structures on the wafer in such a way that they are not illuminated. Radiation passes through transparent mask structures during the imaging operation, for which reason an incidence of light occurs on regions of the wafer that are covered by transparent mask structures. The wafers are usually formed in such a way that their structure changes (for example, a layer is etched away) in the event of incidence of light, as a result of which, during the imaging operation of a mask on a wafer, semiconductor structures arise on the wafer.

In order for the semiconductor circuits to become ever smaller, more powerful and cheaper, many different physical effects have to be circumvented. In particular, it is necessary to circumvent constructive interference effects in optical lithography in a manner such that subwavelength circuit elements can be imaged at a given wavelength. The prior art, in particular A. K. Wong, “Resolution Enhancement Techniques in Optical Lithography,: SPIE Press, Vol. TT 47, March 2001, which is incorporated herein by reference, discloses a dipole diaphragm as a particularly favorable diaphragm for the imaging operation, the dipole diaphragm having two diaphragm openings instead of one opening like a conventional circular diaphragm. The mid-points of the two diaphragm openings define a dipole axis, which is important for the imaging properties of the mask onto the wafer. Mask structures that are oriented parallel to the dipole axis are imaged differently than mask structures that are oriented perpendicular thereto and parallel to an imaging axis. The dipole axis is very well suited to use in the imaging of semiconductor structures oriented parallel to the imaging axis. In actual fact, dipole diaphragms are usually only used for producing semiconductor circuits, which almost exclusively have semiconductor structures oriented parallel to one another and in the imaging direction, the so-called main semiconductor structures. For this purpose, main mask structures likewise oriented parallel to the imaging axis are provided on the mask.

The main semiconductor structures arranged parallel to one another have to be partly interconnected in order to provide electrical contacts between the main semiconductor structures. It has been shown, however, that mask structures that are oriented parallel to the dipole axis are imaged only with a very poor quality as semiconductor structures on the wafer during the imaging operation.

### SUMMARY OF THE INVENTION

In one respect, the invention provides a possibility of enabling a wafer to be produced whilst utilizing the advantages of a dipole diaphragm such that main semiconductor structures oriented parallel to one another are connected to one another better on a wafer.

According to embodiments of the invention, at least one connecting mask structure oriented obliquely with respect to the dipole axis at least in sections is formed on the mask, which structure connects at least two main mask structures to one another.

In preferred embodiments, the connecting mask structure is formed in such a way that during the imaging of the mask onto the wafer, at least one connecting semiconductor structure is produced such that at least two main semiconductor structures are connected to one another by the connecting semiconducting structure. Depending on the imaging technology used (dark field or bright field technology), the connecting semiconductor structure is formed either in conductive fashion or in non-conductive fashion on the wafer. In general, the semiconductor circuit to be created is very complex, for which reason a multiplicity of main semiconductor structures and connecting semiconductor structures have to be produced by means of the mask. Therefore, the mask also has a plurality of main mask structures for the purpose of producing the main semiconductor structures, and also a multiplicity of connecting mask structures for the purpose of producing a multiplicity of connecting semiconductor structures.

As a result of the oblique formation of the connecting mask structure, it takes up space on the mask both in the direction of the dipole axis and in the direction of the imaging axis.

Since mask structures running parallel to the imaging axis can be imaged best by means of the dipole diaphragm and mask structures running parallel to the dipole axis can be imaged worst by means of the dipole diaphragm, connecting mask structures running obliquely with respect to the two axes are imaged with a better quality on the wafer than mask structures oriented parallel to the dipole axis. In this case, the connecting mask structure is oriented such that it is inclined at an angle α relative to the dipole axis. In this case, α preferably lies between about 0° and about 90°. This means, therefore, that the connecting mask structure is inclined by 90°−α relative to the imaging axis.

In a particularly preferred embodiment, the angle a lies between about 30° and about 60°. In this angular range, a happy medium is found between achievable imaging quality and the loss of space on the mask through the extent of the connecting mask structures in the imaging direction. Although the connection is not created by a direct path between the main structures, in return it is provided such that it exhibits an acceptable quality.

In this case, the angle α is preferably inclined approximately by 45° relative to the dipole axis and at the same time also relative to the imaging axis. An angle α of 45° is the simplest technically that can be realized on a mask.

The connecting mask structure is particularly advantageously formed in stepped fashion. If an oblique connecting mask structure is formed rectilinearly from one main mask structure to another main mask structure, then imaging errors may furthermore occur under certain circumstances during the imaging operation. A remedy is afforded by a connecting mask structure in which the connecting mask structure comprises a plurality of sections that are oriented differently from one another in sections. This gives rise to a staircase form or stepped form. Connecting mask structures having at least one step have been found to be advantageous in the case of the staircase design.

In one embodiment, the stepped connecting mask structure at least in sections comprises sections oriented parallel to the imaging axis. These sections are imaged particularly well by the dipole diaphragm. Therefore, at least these sections of the connecting mask structure are imaged with a very good quality, while the obliquely inclined sections of the connecting mask structure that are formed in between only have to be imaged in a shorter form, in which case, on account of the reduced dimensions, not as many errors arise and the quality of the overall imaging of the connecting mask structure is increased.

In this case, the stepped connecting mask structure is advantageously formed as a sequence of sections inclined at the angle β relative to the dipole axis and sections oriented parallel to the imaging axis, where the following holds true: 0≦β<90°.

The individual sections of the stepped connecting mask structure are preferably made as small as can be realized on the mask. Since all mask structures are very small, certain physical limits are imposed on the layout of the mask. The more steps a connecting mask structure has, the higher the imaging quality.

In one embodiment, the average inclination of the stepped connecting mask structure in relation to the imaging axis is minimized to an extent permitted by the external conditions of the layout of the semiconductor structures on the wafer. The average inclination of the stepped connecting mask structure is to be understood to mean the slope of the connecting mask structure in relation to the imaging axis. Since certain fixed points on the semiconductor wafer, such as, e.g., contact points for electrical contact-connections, are positioned at fixed locations of the layout, the stepped connecting mask structure cannot be extended in arbitrarily planar fashion in the direction of the imaging axis. By means of the semiconductor layout, limits are thereby imposed on the existing dimensions of the connecting semiconductor structure, which limits also apply to the connecting mask structure. For this reason, the stepped connecting mask structure is made only as planar as is permitted by the layout of the semiconductor structures on the wafer. This optimization between available space and the dimensions of the connecting mask structure in the direction of the imaging axis can also be applied to connecting mask structures that run rectilinearly, that is to say, which are not formed in stepped fashion.

The mask is particularly advantageously formed from a tritone substrate and provided for use in half tone technology. This is currently the most often used form of lithography masks in the production of semiconductor circuits. However, the invention's layout of a lithography mask can in principle be applied to all lithography masks that are exposed by means of a dipole diaphragm. They include all customary mask lithographies such as phase masks, dark field and bright field masks or conventional masks.

Preferably, the mask structures are formed in a manner smaller than the light wavelength provided for the imaging, which optimizes the utilization of the available space accorded to the semiconductor circuit, and minimizes the overall extent of the masks.

The mask is advantageously formed in such a way that it is suitable for use during imaging with a light wavelength of 193 nm. In this case, it is possible to produce semiconductor structures with a width of approximately 90 nm such as are used in 90 nm circuit technology.

In one embodiment according to the invention, the connecting semiconductor structures are bit line rewirings, which are imaged on the wafer by the connecting mask structures. In this case, bit line wirings are created as main semiconductor structures on the wafer by the main mask structures.

The invention furthermore includes methods for producing a semiconductor circuit with an imaging system. Furthermore, an imaging system can be used according to embodiments of the invention for producing a semiconductor circuit.

### BRIEF DESCRIPTION OF THE DRAWINGS

The invention is explained in more detail below on the basis of exemplary embodiments illustrated in figures, in which:

FIG. 1a shows a layout for a semiconductor circuit with main and connecting semiconductor structures;

FIG. 1b shows a wafer image after the imaging of a mask having a form corresponding to the layout of FIG. 1 a as prior art;

FIG. 2a shows a layout for a semiconductor circuit analogously to FIG. 1a;

FIG. 2b shows a mask for imaging onto a wafer for producing a semiconductor circuit according to FIG. 2a;

FIG. 2c shows a wafer image with semiconductor structures after the imaging of the mask from FIG. 2b onto the wafer;

FIG. 3a shows a schematic illustration of a circular diaphragm;

FIG. 3b shows a schematic illustration of a dipole diaphragm;

FIG. 4 shows a schematic illustration of a tritone substrate;

FIG. 5a shows a schematic illustration of a mask with stepped connecting mask structures;

FIG. 5b shows an electron microscope micrograph of a detail from the mask from FIG. 5a; and

FIG. 5c shows an electron microscope micrograph of a wafer after the imaging of k from FIG. 5a on the wafer.

The following list of reference symbols can be used in conjunction with the figures:

| | | | |
|---|---|---|---|
| 1 | Circular diaphragm | 10′ | Main semiconductor structure on the wafer |
| 1a | Opaque region of the circular diaphragm | 11′ | Non-conductive region on the wafer |
| 1b | Transmissive region of the circular | 12′ | Contacts on the wafer |
| | diaphragm | | |
| 2 | Dipole diaphragm | 13′ | Connecting semiconductor structure on the |
| | | | wafer |
| 2a | Opaque region of the dipole diaphragm | 14′ | Short circuit |
| 2b | Transmissive region of the dipole | 15′ | Semiconductor circuit |
| | diaphragm | | |
| 3 | Chromium | 20 | Main mask structure |
| 4 | Halftone material | 21 | Vitreous region |
| 5 | Glass | 23 | Connecting mask structure |
| 10 | Main semiconductor structure in the layout | 23-1 | Section inclined at 45° with respect to the |
| | | | dipole axis |
| 11 | Non-conductive region in the layout | 23-2 | Section parallel to the imaging direction |
| 12 | Contacts in the layout | 25 | Mask |
| 13 | Connecting semiconductor structure in the | x | Imaging axis |
| | layout | | |
| 15 | Layout of a semiconductor circuit | y | Dipole axis |

### DETAILED DESCRIPTION OF ILLUSTRATIVE EMBODIMENTS

In the figures, mutually corresponding or similar features have the same reference symbols.

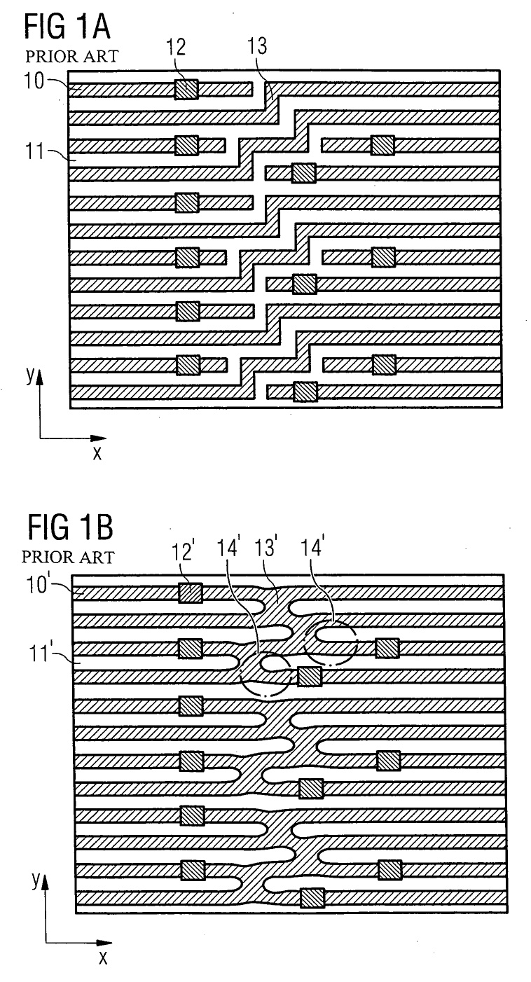

FIG. 1a shows a layout for a semiconductor circuit, which comprises a plurality of elements, in a schematic illustration.

The illustration shows semiconductor tracks as main semiconductor structures 10, connecting semiconductor structures 13, contact points 12 and intervening interspaces as non-conductive regions 11.

The conductor tracks are principally oriented along a first direction, the x direction in FIG. 1a. The x direction is the primary imaging direction since the semiconductor circuit of FIG. 1a is produced by exposing a lithography mask with a dipole diaphragm, which achieves a particularly good imaging quality along one direction.

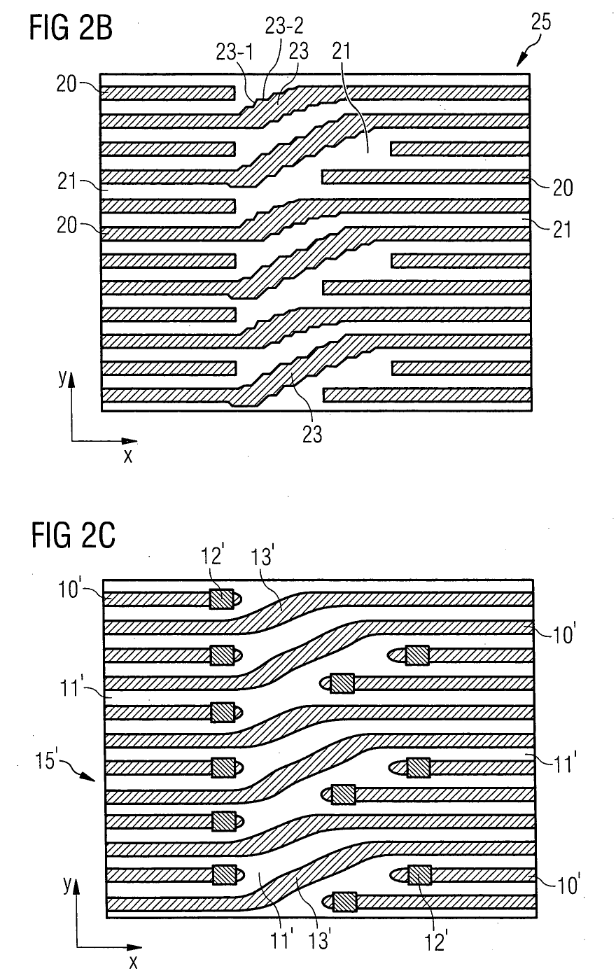

FIG. 3b shows such a dipole diaphragm 2, which essentially comprises an opaque region 2a in which two circular diaphragm openings 2b are cut out. Only the circular diaphragms 2b are light-transmissive, while the region 2a is formed in light-opaque fashion. The axis defined by connecting the mid-points of the two diaphragm openings 2b is referred to as the dipole axis y. Mask structures oriented along the dipole axis y can only be imaged with a very poor quality on a wafer by means of a dipole diaphragm. The imaging axis x runs perpendicular to the dipole axis y. Mask structures oriented parallel to the imaging axis x, that is to say “in the imaging direction,” are imaged with a particularly good quality by a dipole diaphragm 2.

In this case, the diaphragm openings 2b of the dipole diaphragm 2 do not have to be formed in exactly circular fashion. What is essential is that the dipole diaphragm 2 has two diaphragm openings. The latter may, depending on the semiconductor structures to be produced, also be crescent-shaped or be provided with diaphragm openings delimited in jagged fashion.

In comparison with a conventional circular diaphragm 1—illustrated in FIG. 3a—having a light-opaque region la in which a single circular opening 1b serves as a diaphragm, the dipole diaphragm 2 achieves a better quality during the imaging of mask structures oriented in the imaging direction x, and a worse quality in the diaphragm opening direction y.

This is the reason why most of the semiconductor structures of the layout in FIG. 1a are oriented parallel to the imaging axis x and, therefore, run parallel to one another. Semiconductor structures oriented parallel to the imaging axis are referred to as main semiconductor structures 10. In the semiconductor circuit whose layout is shown in FIG. 1a, the main semiconductor structures 10 are intended to be formed in conductive fashion and are separated from one another by non-conductive regions 11. The non-conductive regions 11 correspond to the interspaces between the conductive regions of the semiconductor circuit, such as, e.g., the main semiconductor structures 10 and the contacts 12.

In order to provide connections between the various main semiconductor structures 10, individual connecting semiconductor structures 13 run perpendicular to the main semiconductor structures 10 and parallel to the dipole axis. The connecting semiconductor structures 13 are intended to provide electrical contact-connections between the main semiconductor structures 10.

Depending on the function of the semiconductor circuit, variously localized contacts 12 are provided on the layout and are provided for contact-connecting the semiconductor circuit to electrical elements or lines, which are not illustrated. In order to produce a semiconductor circuit having the layout of FIG. 1a, a mask is exposed on a wafer, a dipole diaphragm, such as the dipole diaphragm 2 from FIG. 3b, being used in this case. In the prior art, masks used for this purpose have the same layout as the semiconductor circuits to be produced. Accordingly, light-opaque structures on a mask correspond to the conductive structures (that is to say the main semiconductor structures 10 and the connecting semiconductor structures 13), and transparent structures on the mask correspond to the non-conductive regions 11 on the semiconductor circuit. As an alternative, depending on the type of lithography, transparent regions on the mask can also be assigned to the conductive semiconductor structures, while opaque regions on the mask are assigned to the non-conductive regions.

With a mask corresponding precisely to the layout of FIG. 1a, a wafer corresponding to the wafer of FIG. 1b is produced during the imaging of the mask on a wafer by means of a dipole diaphragm. Although the main semiconductor structures 10′ are formed well on the wafer, the connecting semiconductor structures 13′ are formed in widened fashion. On the wafer this gives rise to contact-connections between semiconductor structures, which were not provided in the layout of FIG. 1a. By way of example, the details from the wafer of FIG. 1b, which are marked with a circle, exhibit short circuits 14′ between individual main semiconductor structures 10′. Such short circuits 10′ lead to malfunctions of the semiconductor circuit.

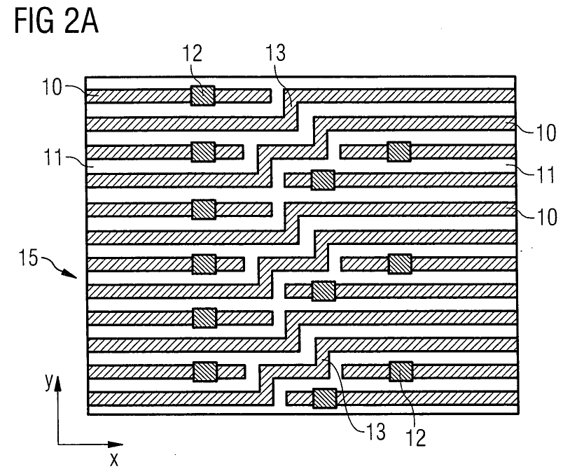

The invention will now be explained with reference to FIGS. 2a, 2b and 2c. FIG. 2a shows the layout 15 of a semiconductor circuit corresponding to the layout of FIG. 1a. Main semiconductor structures 10, connecting semiconductor structures 13, contacts 12 and non-conductive regions 11 are shown in the layout 15.

A mask that includes the layout 15 is not used for the imaging. Rather, according to embodiments of the invention, the mask 25 illustrated in FIG. 2b is used. Main mask structures 20 of the mask 25 correspond to the main semiconductor structures 10 of the layout 15. No separate structures are provided on the dipole mask 25 at the position of the electrical contacts 12 in the layout 15. At the positions assigned to the electrical contacts 12, main mask structures 20 are formed in the dipole mask 25. In order to produce the non-conductive regions 11, vitreous regions 21 are provided on the mask 25. In the regions in which locally only main semiconductor structures 10 are provided in the layout 15, the layout of the mask 25 corresponds one-to-one to the layout 15 from FIG. 2a. In these regions, the main mask structures 20 and also the vitreous regions 21 situated in between are oriented parallel to the imaging axis x. The electrical contacts 12 are fixed points in the layout 15 of FIG. 2a at the position of which main semiconductor structures 10 are provided in the dipole mask 25.

The connecting mask structures 23 in the mask 25 have been altered in comparison with the layout 15, however, which connecting mask structures are intended to provide the connecting semiconductor structures 13 in the layout 15 after the imaging of the mask on the wafer. The connecting mask structures 23 are not oriented parallel to the dipole axis y, but rather have a stepped form, the steps being formed from a first main mask structure 20 to a main mask structure 20 which is offset parallel thereto. The connecting mask structures 23 are composed of mask structures 23-1 running at an angle of 45° relative to the dipole axis y and mask structures 23-2 oriented parallel to the imaging axis x. Consequently, the steps, therefore, do not consist of a sequence of horizontal and vertical surfaces as in the case of a real staircase, but rather of surfaces, which are inclined at an angle of 45°, adjoined by a surface that is oriented parallel to the imaging axis, etc.

During the imaging of the mask 25, although the connecting mask regions 23-1 inclined at 45° are not imaged with a quality that is as good as the main mask structures 20, they are none the less imaged with a better quality than mask structures oriented in the direction of the dipole axis y. Moreover, the mask structures 23-2 of the connecting mask structure 23 which are oriented parallel to the imaging axis x are imaged with a very good quality in the same way as the main mask structures 20. This means that the quality of the imaging of the entire connecting mask structure 23 increases all the more, the more mask structures 23-2 oriented parallel to the imaging direction x the connecting mask structure 23 has.

The quality likewise increases the greater the length with which the mask structures 23-2 oriented parallel to the imaging axis x are formed. Therefore, in the mask 25 the dimensions of the connecting mask structures 23 in the imaging direction x are maximized. The maximum extent of a connecting mask structure 23 in the imaging direction x is principally dependent on the electrical contacts 12 in the layout 15 of FIG. 2a, the position of which is also fixed on the dipole mask 25. Moreover, the vitreous regions 21 between the connecting mask structures 23 and the remaining conductive regions on the mask 25 have to have predetermined minimum dimensions in order to avoid short circuits between the conductive regions on the wafer.

In principle, the sections 23-1 and 23-2 with the connecting mask structure 23 may also be arranged at other angles with respect to one another.

The dimensions shown in FIG. 2b correspond to the minimum dimensions permitted for the mask. The quality of the imaging of the connecting mask structures is increased by using the minimum dimensions. During production, orientations of the structures relative to the dipole axis y at an angle of 0°, 90° (like the main mask structures) and 45° can be realized on a mask. Therefore, structures that are at one of these angles with respect to the dipole axis y were produced during the production of the masks.

In the case of alternative types of masks, however, other angles may also be realized under certain circumstances. The angles of the connecting mask structures 23 oriented obliquely with respect to the dipole axis preferably lie between about 30° and about 60°.

In the embodiment shown in FIG. 2b, the angles of inclination of the individual sections of the connecting mask portion 23 relative to the dipole axis y are alternately 45° (mask structures 23-1) and 90° (mask structures 23-2). As an alternative thereto, however, sequences of, for example, 30°−90°−60°−90°−30° etc., or similar sequences could also be used.

It has been shown in experiments that it is particularly favorable to form at least one step in the connecting mask structure 23.

FIG. 2c shows semiconductor structures on a wafer 15′ which were produced by the imaging of the mask 25 from FIG. 2b. The main semiconductor structures 10′, which were imaged by means of the main mask structures 20, are imaged almost without any errors. The non-conductive regions 11′ and the contacts 12′ were also reproduced well by the corresponding mask regions of the mask 25.

In the wafer image 15′, the stepped connecting mask structures 23 are imaged as oblique connecting semiconductor structures 13′. The average slope of the connecting semiconductor structures 13′ essentially corresponds to the average slope of the stepped connecting mask structures 23 of the mask 25. However, the connecting semiconductor structures 13′ no longer exhibit a stepped form, but rather have an essentially smoothed form. Furthermore, the connecting semiconductor structures 13′ are formed such that they are somewhat wider than the main semiconductor structures 10′. With the use of a light source having a wavelength of 193 nm, the width of the main semiconductor structures 10′ corresponds approximately to 90 nm. The width of the semiconductor structures corresponds to the minimum width which can still be produced with an acceptable quality on the wafer using the wavelength intended for the imaging.

In the exemplary embodiment shown in FIG. 2c, the non-conductive regions 11′ also have a width of approximately 90 nm. The connecting semiconductor structures 13′ may have width fluctuations of up to 20% without influencing the functioning of the semiconductor circuit.

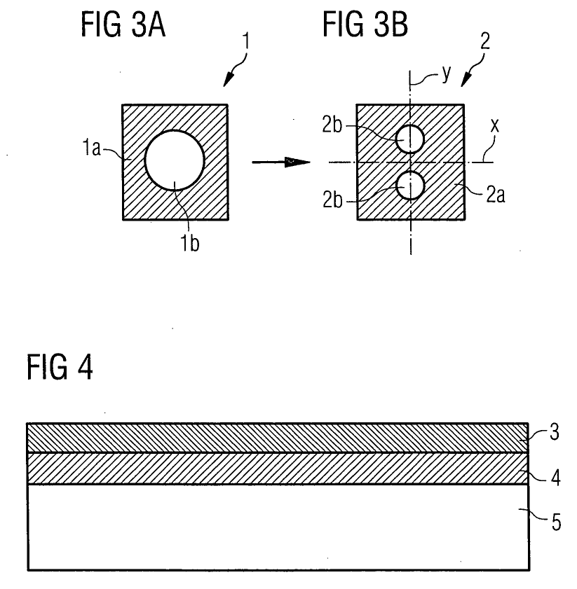

FIG. 4 shows a tritone substrate used for producing a tritone mask. The bottommost and widest layer of the tritone substrate is composed of glass 5. A halftone layer 4 composed of MoSi, for example, is formed above it. An opaque chromium layer 3 is formed above that as the topmost layer. Depending on whether a conductive structure or a non-conductive structure (in or outside an electrical contact as fixed point) is intended to be produced by means of the region of the mask, the position on the tritone mask, which is assigned to the region, is not etched at all, is freed of the chromium layer or is etched free down to the glass layer.

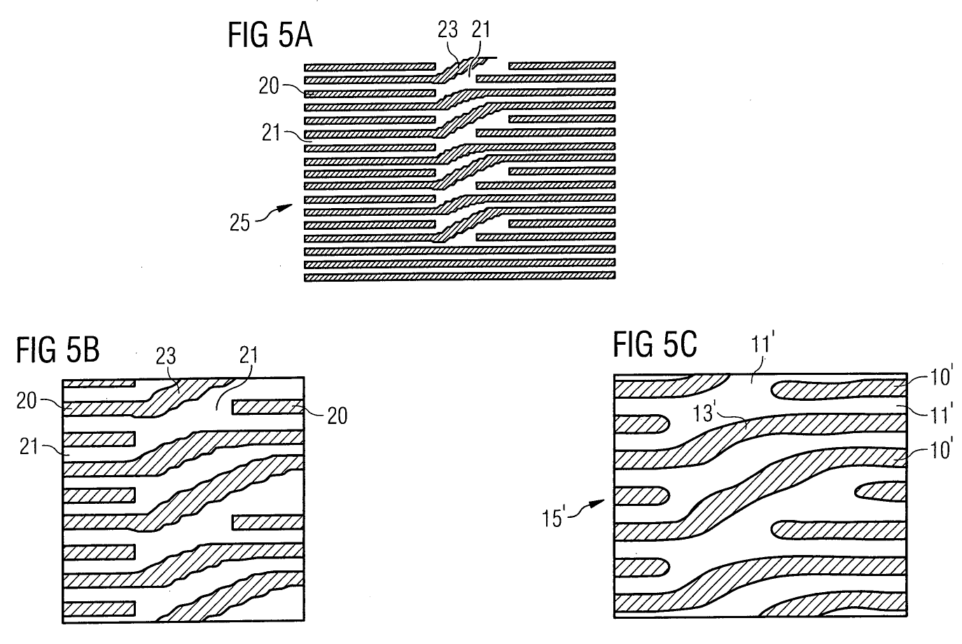

FIG. 5a once again shows the mask 25 in a larger detail. The main mask structures 20 and the connecting mask structures 23 are covered by the halftone material, and the vitreous regions 21 are etched free down to the layer that can be seen as the bottommost glass layer 5 in FIG. 4.

FIGS. 5b and 5c are schematic diagrams of electron microscope micrographs, FIG. 5b showing a detail from the mask of FIG. 5a, and FIG. 5c showing the result of a process for producing a wafer 15′. They reveal that the width of the connecting semiconductor structures 13′ varies only in an acceptable range.

The main semiconductor structures 10′ are formed as a metal track on the wafer 15′ and the connecting semiconductor structures 13′ provide bit line rewirings.

What is claimed is:

1. A method for making a semiconductor circuit, the method comprising:
providing a dipole diaphragm having two diaphragm openings arranged one adjacent the other along a dipole axis;
providing a mask having mask structures arranged in a pattern, the mask structures including main semiconductor structures that are arranged parallel to an imaging axis running perpendicular to the dipole axis, the mask structures further including at least one connecting mask structure oriented obliquely with respect to the dipole axis at least in sections, the connecting mask structure connecting at least two main mask structures to one another;
directing radiation through the dipole diaphragm and the mask and toward a semiconductor wafer so as to form a pattern on the semiconductor wafer, the pattern being based on the mask structures; and
changing a structure of the semiconductor wafer in accordance with the pattern.

2. The method of claim 1, wherein the connecting mask structure is oriented at an angle α relative to the dipole axis, wherein 0°<α<90°.

3. The method of claim 2, wherein 30°≦α≦60°.

4. The method of claim 3, wherein the angle a is substantially 45°.

5. The method of claim 1, wherein the connecting mask structure is at least partly formed in stepped fashion.

6. The method of claim 5, wherein the stepped connecting mask structure comprises a plurality of sections that are oriented parallel to the imaging axis.

7. The method of claim 6, wherein the connecting mask structure comprises a plurality of sections oriented at the angle β relative to the dipole axis in addition to the plurality of sections oriented parallel to the imaging axis.

8. The method of claim 6, wherein ones of the sections have minimum dimensions that can be realized on the mask.

9. The method of claim 5, wherein an angle between the average inclination of the stepped connecting mask structure and the imaging axis is minimized to an extent permitted by the external conditions of the layout of the semiconductor structures on the wafer.

10. The method of claim 1, wherein the mask is formed from a tritone substrate and is provided for use in half tone technology.

11. The method of claim 1, wherein the radiation has a wave length and wherein the mask structures are at least partly formed in a manner smaller than the wavelength of the radiation.

12. The method of claim 1, wherein changing a structure of the semiconductor wafer comprises forming structures have a minimum of about 90 nm.

13. The method of claim 1, wherein changing a structure of the semiconductor wafer comprises forming structures have a minimum of about 65nm or less.

14. The method of claim 1, wherein directing radiation comprises directing radiation having a wavelength of about 193 nm.

15. The method of claim 1, wherein the connecting mask structures are provided for producing bit line rewirings on the wafer.

16. The method of claim 1, wherein changing a structure of the semiconductor wafer comprises etching a layer at an upper surface of the semiconductor wafer.

17. An imaging system comprising:
a dipole diaphragm having two diaphragm openings arranged one adjacent the other along a dipole axis; and
a mask having mask structures for producing semiconductor structures on a wafer by imaging the mask onto the wafer using the dipole diaphragm, the mask for producing main semiconductor structures on the wafer, the main mask structures being parallel to an imaging axis running perpendicular to the dipole axis, wherein at least one connecting mask structure oriented obliquely with respect to the dipole axis at least in sections is formed on the mask, the connecting mask structure connecting at least two main mask structures to one another.

18. The imaging system of claim 17, wherein the mask is a lithography mask.

19. The imaging system of claim 17, wherein the connecting mask structure comprises a plurality of sections that are oriented parallel to the imaging axis.

20. A method of using an imaging system, the method comprising:
providing an imaging system, the imaging system comprising:
a dipole diaphragm having two diaphragm openings arranged one adjacent the other along a dipole axis; and
a mask having mask structures for producing semiconductor structures on a wafer by imaging the mask onto the wafer using the dipole diaphragm, the mask for producing main semiconductor structures on the wafer, the main mask structures being parallel to an imaging axis running perpendicular to the dipole axis, wherein at least one connecting mask structure oriented obliquely with respect to the dipole axis at least in sections is formed on the mask, the connecting mask structure connecting at least two main mask structures to one another; and
using the imaging system to produce a semiconductor circuit.
